(19) United States
(12) Patent Application Publication
(10) Pub. No.: US 2014/0227461 A1
(43) Pub. Date: Aug. 14, 2014

(54) Multiple Beam Pulsed Laser Deposition Of Composite Films

(71) Applicant: Dillard University, New Orleans, LA (US)

(72) Inventors: Abdalla Darwish, Kenner, LA (US); Sergey Sarkisov, Huntsville, AL (US)

(21) Appl. No.: 14/158,567

(22) Filed: Jan. 17, 2014

Related U.S. Application Data
(60) Provisional application No. 61/850,330, filed on Feb. 14, 2013.

(51) Int. Cl. C23C 14/22

(52) U.S. Cl. CPC C23C 14/22
USPC 427/596; 118/722

(57) ABSTRACT

A system and method for multiple beam laser deposition of thin films wherein separate laser beams are used to ablate material from separate targets for concurrent deposition on a common substrate. The laser beams may have the same or different wavelengths, energies, or pulse rates. The targets may be similar or differing classes of materials including, but not limited to polymers, organics, inorganics, nanocrystals, solutions, or mixtures of materials. One or more targets may be disposed on a tiltable mount to adjust the direction and mixing of the ablation plumes from the multiple targets. The target surface may be scanned by moving the target in one or more axes. Multiple ablation modes may be concurrently employed at the various targets, including, but not limited to pulsed laser, MAPLE, IR-MAPLE and other modes. A polymer-nano-composite film example is disclosed.

### RELATED APPLICATIONS

This application claims the benefit under 35 USC 119(e) of provisional application Ser. No. 61/850,330, titled: “Method and Apparatus for multi-beam pulsed laser deposition of thin films,” filed Feb. 14, 2013 by Abdalla Darwish et al.

### GOVERNMENT LICENSE RIGHTS

The U.S. Government has a paid up license in this invention and the right in limited circumstances to require the patent owner to license others on reasonable terms as provided for by the terms of contract FA90550-10-1-0199 and FA9550-10-1-0198 awarded by Air Force Office of Scientific Research.

### TECHNICAL FIELD

The present invention pertains generally to the field of deposition of thin films, more particularly to the deposition of films in a vacuum or gas atmosphere using laser ablation of source material.

### BACKGROUND

There is a great need for composite films deposited on different substrates. Applications vary from miniature chemical and biosensors, light emitters, detectors of e-m radiation from IR to gamma, etc. Unique features of the pulsed laser deposition (PLD), such as control of film thickness with good accuracy, uniform coating, and good control of the film composition.

Current techniques are highly dependent on specific materials and laser wavelengths that have been found to be useful. Thus, there is a need for improved techniques that provide good performance with a wider range of materials and produce films of good uniformity and composition.

### BRIEF DESCRIPTION

The present disclosure relates to a system and method for multiple beam laser deposition of thin films wherein separate laser beams are used to ablate material from separate targets for concurrent deposition on a common substrate. The lasers may be the same or different wavelengths, powers, or pulse rates. The targets may be similar or differing classes of materials including, but not limited to polymers, organics, inorganics, nanocrystals, solutions, or mixtures of materials. One or more targets may be disposed on a tiltable mount to adjust the direction and mixing of the ablation plumes from the multiple targets. The target surface may be scanned by moving the target in one or more axes. Multiple ablation modes may be concurrently employed at the various targets, including, but not limited to pulsed laser, MAPLE, IR-MAPLE and other modes.

Numerous substantial benefits may arise from the system as disclosed.

Materials of differing properties may be concurrently and/or simultaneously deposited to produce a film of uniform properties. The differing materials may be ablated by processes tailored to each material, with separate selection of laser power, wavelength, fluence, and pulse rate. For example, a laser wavelength may target an absorption band of a particular target, or may be selected for minimum damage to the material. Pulse rate may be adjusted to set the material mixture ratio in the film. Target composition may be formulated for optimal ablation of each material, for example, allowing cryogenic solutions on one target and heated solids on another target.

In a further feature, one or more targets may be disposed on a pivotable mount to allow adjustment of the ablation plume taking into account interaction with other plumes for best uniform coverage of the combined ablation plumes of the various targets.

In a further feature, one or more targets may be scanned relative to the laser beam to utilize an area of the target larger than the focused laser beam. In one variation, the target may be scanned according to a raster pattern. The raster pattern may have a radial component and may have a tangential or circular component. The raster may be under computer control. In a further variation, the raster pattern may be an arbitrary pattern.

In one variation, one or more targets may be mounted on a rotatable carousel. A pivotable target mount may be disposed on the carousel and rotatable with the carousel. The target may be mounted on a linear slide on the pivotable surface of the pivotable mount. The slide axis may be oriented radially in respect to the rotation axis of the carousel, and may tilt with the pivotable surface of the pivotable mount. The linear slide and the carousel may be controllable by computer. The computer control may command back and forth radial motion incremented by rotational motion to raster scan the target. Alternatively a combination of radial and rotational motion may be used to form a rectilinear raster scan or an arbitrary scan pattern.

In one variation, the rotatable carousel may have sufficient rotation range to move multiple targets into position. For example, three targets may be set up on one or more pivotable slides. When one target is depleted, a second target on the same slide may be moved into position. Alternatively or in addition, a second pivotable slide may be moved into position. Thus, multiple targets may be utilized using the same laser beam. The multiple targets may have the same material, thus increasing the run time, or the multiple targets may have different materials, thus enabling multi-layer films.

In further variations, the disclosure includes related methods, e.g. a method for depositing a composite film on a substrate based on:
1. directing a plurality of pulsed laser sources to impinge a respective plurality of targets and produce a respective plurality of plumes, each target of said respective plurality of targets containing a respective material for deposition on said substrate;
2. orienting said respective plurality of targets to direct each plume of said respective plurality of plumes to a plume mixing volume in front of said substrate;
3. triggering said plurality of laser sources to produce respective plumes concurrently in time to mix said plumes in said plume mixing volume front of said substrate and concurrently deposit said respective materials to produce a composite layer on said substrate.

### ADVANTAGES

Conventional PLD is typically configured to produce one thin film at a time and one material at a time. Thus, producing either single layer of one material, or multiple layers of the same or different materials. As a consequence, it is very difficult to produce materials similar to an evenly doped crystal. In a conventional crystal growth process, either from a solution or melt, when the crystal is intended to be evenly doped, for instance, with transitional metal ions, the dopants take evenly spaced places in the main ion structure, or interstitial sites during the growth since both materials grow at the same time in situ. So, the need to fabricate a PLD thin film analogous to an evenly doped crystal has not been met before. The proposed method and apparatus uses at least two different beams at the same time to ablate two different materials in situ, not one after another and not alternating between targets using the same laser beam. The multiple simultaneous beams produce one composite layer at a time. Therefore, having at least two beams instead of one allows the interaction between different species, adds the ability to control the proportion of the dopant material added, and allows the dopant ions to migrate and settle in their position in the crystal. The two beams thus allow improved accuracy of the control of the process to tailor the properties of doped thin film in a desirable way. The overlap of the plumes, may be perfected by adjusting the tilt of the target holders.

### INDUSTRIAL APPLICATIONS

The apparatus and method can be used in commercial applications using polymer nano-composite coatings, such as (a) chemical and bio-sensors (polymers doped with indicator dyes and metal nano-particles for chemical sensing or polymers doped with antibodies and nano-particles for bio-sensing); (b) fluorescent coatings and scintillation radiation sensors (polymers doped with nano-particles of the oxides and salts of the rare earth elements) and others. The system may be of great interest to the petro-chemical industry (using sensors of hazardous chemical species), food and agriculture industries (using sensors of hazardous bio-species); nuclear power industry (miniature sensors of harmful radiation); home land security and defense (detectors of weapons of mass destruction, “dirty bombs”, and improvised explosives) and others.

One exemplary use for the upconversion fluorescence films disclosed herein is for use as an anticounterfeit security feature. The film may be deposited in a particular position or pattern on an object such as a product or currency note. The film would be unnoticed by the consumer under ordinary lighting. However, when illuminated by the right infrared illumination, the film would emit a visible green or blue light, revealing the pattern to a security screener and verifying authenticity. A product failing to contain the mark would be likely to be a counterfeit.

These and further benefits and features of the present invention are herein described in detail with reference to exemplary embodiments in accordance with the invention.

### BRIEF DESCRIPTION OF THE FIGURES

The present invention is described with reference to the accompanying drawings. In the drawings, like reference numbers indicate identical or functionally similar elements. Additionally, the left-most digit(s) of a reference number identifies the drawing in which the reference number first appears.

FIG. 1 presents a schematic of an exemplary dual pulsed laser deposition system in accordance with the present disclosure.

FIG. 2 shows a cross section view of the system of FIG. 1.

FIG. 3 depicts an exemplary schematic diagram of an alternative multiple laser system and illustrates additional optional features.

FIG. 4 is a top view of the DPLD system, which shows the two laser beams with respect to the target holder with two targets.

FIG. 5 shows the fluorescence spectrum of NaYF₄:Er³⁺, Yb³⁺ powder (compound “a”) illuminated with 980-nm laser radiation.

FIG. 6 shows the fluorescence spectrum of NaYF₄:Ho³⁺, Yb³⁺ powder (compound “b”) illuminated with 980-nm laser radiation.

FIG. 7 shows the fluorescence spectrum of NaYF₄:Tm³⁺, Yb³⁺ powder (compound “c”) illuminated with 980-nm laser radiation.

FIG. 8 shows the XRD spectrum of the powder of NaYF₄:Ho³⁺, Yb³⁺ baked at 400° C. Black vertical arrows directed downwards mark the positions of the peaks in the XRD spectrum of the composite PMMA: NaYF₄:Ho³⁺, Yb³⁺ film deposited using DPLD.

FIG. 9 shows the XRD spectrum of the powder of NaYF₄:Tm³⁺, Yb³⁺ baked at 400° C. Black vertical arrows directed downwards mark the positions of the peaks in the XRD spectrum of the composite PMMA: NaYF₄:Tm³⁺, Yb³⁺ film deposited using DPLD.

FIG. 10 shows an AFM scan of the composite film of PMMA: NaYF₄:Er³⁺, Yb³⁺.

FIG. 11 shows an AFM scan of the composite film of PMMA: NaYF₄:Tm³⁺, Yb³⁺.

FIG. 12 shows a fluorescence spectrum of composite film PMMA: NaYF₄:Er³⁺, Yb³⁺ illuminated with 980-nm laser radiation.

### DETAILED DESCRIPTION OF THE PREFERRED EMBODIMENTS

### Laser Deposition Basics

The currently existing laser deposition techniques for polymers can be listed in chronological order of their introduction:

(1) pulsed laser deposition with UV laser (UV-PLD);

(2) matrix-assisted pulsed laser evaporation (MAPLE); and

(3) resonant infra-red pulsed laser deposition (RIR-PLD).

UV-PLD is historically the first method used to deposit polymeric films. Its major difference from PLD for inorganic films is the use of UV radiation either from excimer lasers (193-351 nm) or the 3-rd (355 nm) and the 4-th harmonics (266 nm) of Nd:YAG laser. This is due to the fact that UV radiation is strongly absorbed by most of the polymers. Despite the extensive list of polymer deposited by PLD, the use of PLD for deposition of organic and polymeric materials has provided mixed results at best. Moreover, despite the large number of variables explored in the deposition parameter space by researchers, the quality of the films produced by PLD has only been optimal for a very small number of systems. By using a UV laser in order to ablate various polymeric targets, it is not surprising that the resulting films will tend to show some degree of irreversible decomposition or damage. Given the fact that in these materials the chemical bonds have energies well below the UV photon energies, some degree of photochemistry is expected to occur during the PLD process. Only for a small group of addition polymers such as PTFE, PMMA, etc., does the absorbed UV radiation cause photothermal depolymerization of the starting material resulting in the reversible unzipping of the polymer chains. More often than not, however, the interaction of the UV photons with the polymeric or organic molecules will cause the loss or decomposition of functional groups, or in the case of condensation polymers, the resulting photochemistry will be responsible for the substantial modification of the starting material. Such modifications might be acceptable for some applications, but in general the use of lasers for depositing thin films of polymers requires more subtle approaches than those offered by PLD alone.

MAPLE has recently been demonstrated and promoted by the research team at the Naval Research Laboratory. MAPLE is a variation of conventional PLD. MAPLE provides, however, a more gentle mechanism for transferring polymers from the condensed phase into the vapor phase. In MAPLE, a frozen matrix consisting of a dilute solution (1-5%) of a polymeric compound in a relatively volatile solvent is used as the laser target. The solvent and concentration are selected so that first, the material of interest can dissolve to form a dilute, particulate free solution, second, the majority of the laser energy is initially absorbed by the solvent molecules and not by the solute molecules, and third, there is no photochemical reaction between solvent and the solute. The light-material interaction in MAPLE can be described as a photothermal process. The photon energy absorbed by the solvent is converted to thermal energy that causes the polymer to be heated but the solvent to vaporize. As the surface solvent molecules are evaporated into the gas phase, polymer molecules are exposed at the gas-target matrix interface. The polymer molecules attain sufficient kinetic energy through collective collisions with the evaporating solvent molecules, to be transferred into the gas phase. By careful optimization of the MAPLE deposition conditions (laser wavelength, repetition rate, solvent type, concentration, temperature, and background gas and gas pressure), this process can occur without any significant polymer decomposition. The MAPLE process proceeds layer-by-layer, depleting the target of solvent and polymer in the same concentration as the starting matrix. When a substrate is positioned directly in the path of the plume, a coating starts to form from the evaporated polymer molecules, while the volatile solvent molecules are evacuated by the pump in the deposition chamber. By using MAPLE and PLD together, laser-based techniques could produce polymer nanocomposite films by sequential deposition of polymer and nanoparticle components. Moreover, MAPLE targets can be prepared by adding nanocomponents to the polymer solutions at desired proportions that will be preserved in the deposited nanocomposite film. Using the latter techniques, research team at the University of Virginia has recently fabricated polymer nanocomposites of PMMA and carbon nanotubes (CNTs) with MAPLE. MAPLE targets were prepared by first dissolving PMMA in toluene at a concentration of 3 wt. % using ultrasonication. Composite solutions were produced by adding CNTs to pre-mixed PMMA-toluene solutions to achieve CNT concentrations of 0.1 wt. % relative to the toluene and approximately 3 wt. % relative to the deposited PMMA. Solutions were then poured into Cu target cups and flash frozen using liquid nitrogen. Due to the relatively low melting point of toluene (178 K), liquid nitrogen cold stage was used to maintain the target temperature at approximately 120 K during depositions. The deposition chamber was initially pumped down to a base pressure of approximately 3.3×10⁻³ Pa, and then backfilled to 13.3 Pa using Ar gas. A continuous flow of Ar was bled into the chamber at a rate of 12 sccm (standard cubic centimeters per minute) for the duration of each deposition. The pressure in the chamber was maintained at 13.3 Pa by dynamically throttling the gate valve of a turbo pump system affixed to the chamber. Targets were irradiated at a fluence of 0.30 J/cm2 with a pulsed excimer laser (248 nm wavelength, 25 ns full pulse width at half maximum) operating at a frequency of 5 Hz. The laser beam was rastered across the target surface during the deposition to reduce repetitive irradiation effects. The films were deposited onto p-type, single crystal Si substrates positioned approximately 7 cm from the target. Substrates were heated to temperatures of 315, 337, 359, 381, 403, or 425 K for the duration of each deposition. Substrate heating was found to reduce the surface roughness of the nanocomposite films.

Resonant infrared pulsed laser deposition (RIR-PLD) is a variant of conventional PLD in which the laser is tuned to vibrational modes in the target material. The intense laser irradiation is used to promote the solid phase material to a highly vibrationally excited gas-phase species in the ground electronic state that can be collected on a nearby substrate as a thin film. In the absence of electronic excitation, the complex chemical and physical structure of the organic material is preserved. So far, this approach has been used with polymers in the mid-infrared wavelength range (2-10 μm). Typical chemical bonds and their vibrational modes that have been utilized in RIR-PLD are O—H stretch (vibrational mode wavelength 2.90 μm), C—H stretch (vibrational modes 3.28, 3.30, 3.38, 3.40, 3.42, and 3.45 μm), and C—O stretch (8.96 μm). One variation uses a MAPLE target in the form of emulsion of solvent and ice. RIR-MAPLE used laser radiation at a 2.94 nm in strong resonance with vibrational mode of the hydroxyl O—H bonds in the ice component of the emulsion matrix. In this way, the types of materials that can be deposited using RIR-MAPLE have been significantly expanded. Furthermore, materials with different solvent bond energies can be co-deposited without concern for material degradation and without the need to specifically tune the laser energy to each material solvent bond energy, thereby facilitating the realization of organic/inorganic hybrid nanocomposite thin-films.

### Dual Pulsed Laser Deposition System

The present disclosure relates to a system and method for multiple beam laser deposition of thin films wherein separate laser beams are used to ablate material from separate targets for concurrent deposition on a common substrate. The system results in numerous advantages including, but not limited to:
1) Multiple high-power pulsed laser beams of a variety of wavelengths that can be simultaneously applied to separate targets to deposit a composite film on the same substrate.
2) Variable angle of each target with respect to its laser beam in order to achieve the adjustment of the position and the angle of the corresponding plume with respect to the substrate in order to optimize the size of the region over the substrate where multiple plumes overlap and deposit the composite film of a variable proportion between the components.
3) Combination of the variable angle of the target surface with target lateral motion (with respect to the laser beam) for rastering (i.e., raster scanning) of the target surface to provide smooth and uniform deposition.
4) A rotating target stage capable of switching targets for the laser beams.
5) The target stage combined with the means of target cooling, for example, cooling to the temperature as low as the temperature of liquid nitrogen suitable for typical MAPLE and RIR MAPLE processes.

The apparatus and the method enable:
1. Creating polymer nano-composite films of more uniform mixture of the components because they are simultaneously deposited on the substrate form multiple targets hit by multiple laser beams.
2. Creating polymer nano-composite films of more uniform thickness and distribution of the components along the film due to optimized overlapping of the plumes from multiple targets achieved by the variation of the tilt of each target with respect to its laser beam.
3. Improving the uniformity of the film also due to combination of the lateral motion of the target with respect to its laser beam to achieve rastering and uniform consumption of the target material.
4. Achieving better quality of the polymer (less proportion of monomers and polymer fragments) coating due to the use of MAPLE or RIR MAPLE techniques provided by the cooling stage.
5. Widening the variety of the possible coatings by switching the targets between different laser beams with the use of the rotary target stage.

### Variable Tilt Target Holder

The method uses a new concept of variable tilt of the target in order to change the position of the plume with respect to the substrate and optimize the overlapping between the plumes of different targets.

### Exemplary Multiple Pulsed Laser Deposition System

An exemplary multiple pulsed laser deposition system will now be described in detail with reference to the drawings.

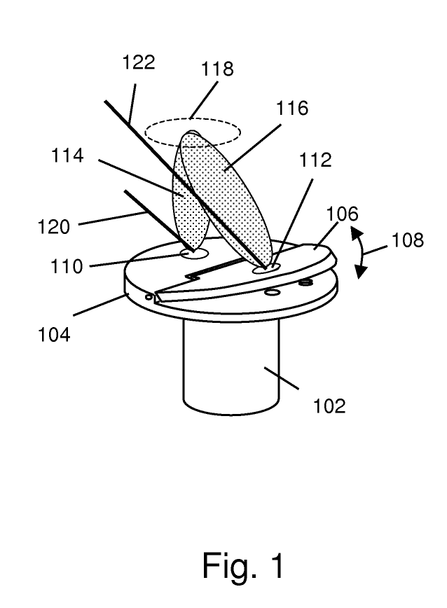

FIG. 1 presents a schematic of an exemplary dual pulsed laser deposition system in accordance with the present disclosure. FIG. 1 illustrates an exemplary target carousel 104 configured to accommodate two separate targets 110, 112 illuminated by two separate laser beams 120, 122. The separate laser beams may have wavelength, energy, fluence, and focus properties individual tailored for each separate respective target. A first target 110 is shown mounted on a rotatable carousel 104. A second target 112 is shown mounted to a tiltable platform 106 on the rotatable carousel 104. The two lasers 120, 122 may produce a first plume 114 and second plume 116 when directed to the respective targets. The two plumes are directed to interact and co-deposit their respective materials on a substrate 118. The tiltable platform 106 may be adjusted to a tilt angle 108 to direct the second plume 116 for optimum interaction with the first plume 114 and even co-deposition of material on the substrate 118. Note, the plumes 114 and 116 depicted in FIG. 1-FIG. 3 are not intended to be accurate drawings of plumes, but only indicative of a region of plume development. The actual plumes continue to develop and deposit material over a substantial portion of the substrate.

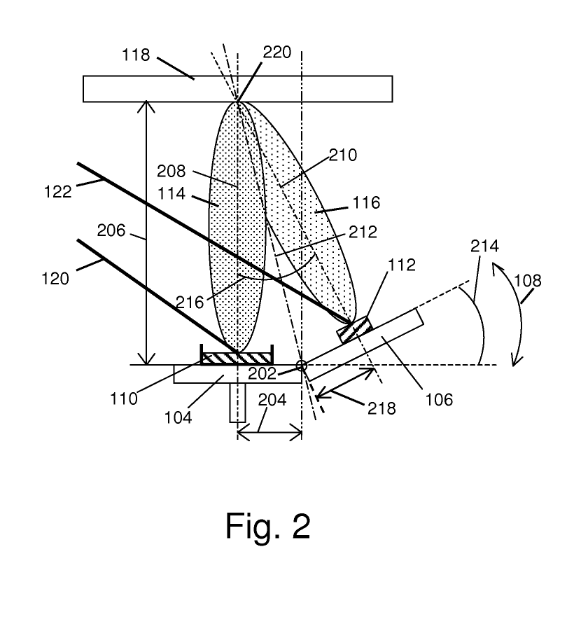

FIG. 2 shows a cross section view of the system of FIG. 1. Referring to FIG. 2, FIG. 2 shows the first laser beam 120; the second laser beam 122; the first target 110 and second target. 112. The first target 110 may be, for example but not limited to frozen polymer solution in case of MAPLE. The second target 112 may be, for example but not limited to a compressed pellet of the powder of an upconversion inorganic material. FIG. 2 further illustrates the holder of the first target 104 may optionally be cooled with liquid nitrogen as desired for MAPLE, for example, and the holder 106 of the second target configured with a hinge 202 to allow variable or adjustable tilt along arc 108. The first target 110 and second target 112 produce respective plumes 114, 116 normal to the surface of each target. The plumes have a respective first axis 208 and second axis 210 normal to the surface of the target at the center of the laser spot. A bisector 212 of the angle 216 between the first and second axis may preferably pass through the hinge 202 axis. A tilt angle 214 is shown. A distance 206 from the tilt axis (hinge axis) to the substrate is shown, and a first plume offset distance 204 from the first plume axis to the hinge axis and perpendicular to the plume axis is also shown. In one exemplary variation a second plume offset distance 218 is equal to the first plume offset distance 204.

The pulsed laser deposition includes the sequence of the processes:
(a) heating the target with the laser pulse;
(b) melting the heated target material followed by its vaporization;
(c) ionizing the atoms of the vaporized target material by the electrons accelerated in the strong electric field of the laser pulse and creating weakly ionized plasma;
(d) expansion of the plume made of the weakly ionized plasma driven by electrostatic repulsion of the positive ions of the target material towards the ambient gas or vacuum separating the target from the substrate;
(e) condensation of the target material from the plume on the substrate and thin film formation.

Since the spread of the plume is driven by electrostatic repulsion, the axis of the plume is normal to the surface of the target regardless of the direction of the incident laser beam. The optimal tilt can be understood from FIG. 2. The target holder is split in two halves: the static holder 104 of the first target 110 and holder 106 of the second target 112 with variable tilt. Holder 106 rotates around hinge 202. The optimal tilt angle θ is reached when the plumes from both targets overlap on the substrate 118, in other words, their axes 208 and 210 intersect on the surface of substrate 118. One can see from FIG. 2 that tilt angle 214 is equal to angle 216 between axes 208 and 210 of the plumes. In case the spots of the targets where the laser beams hit have the same distance from hinge 202, bisector 212 of angle 216 passes through hinge 202 and the point 220 on the surface of substrate 118 where axes 208 and 210 of both plumes intersect. Correspondingly, a desired tilt angle can be calculated as

$$θ = 2 {tan}^{- 1} ( \frac{d}{l} ) , \qquad ( 1 )$$

where,

θ is the desired tilt angle;

d is the distance between the spots of the targets exposed to the laser beams and hinge 212 (distances 204 and 218 in FIG. 2); and

l is the distance between stationary target holder 6 and substrate 118 (distance 206 in FIG. 2).

The desired tilt angle can be pre-set before the laser deposition and adjusted around the pre-set value during the laser deposition process in order to correct possible errors related to the shift of the laser beams along the targets, change of the distance between the targets and the substrate, etc. In one embodiment of the invention, the distance l between substrate 118 and target holder 110 was 1 inch (2.54 cm) and distance d was 0.25 inch (0.635 cm). Correspondingly, the desired tilt angle was 14.0 degrees.

The tilt angle θ may be refined by running test samples with various angles around θ to determine an optimum angle. According to one criterion, the best angle would be the angle that gives the most uniform coverage over a given area of the substrate.

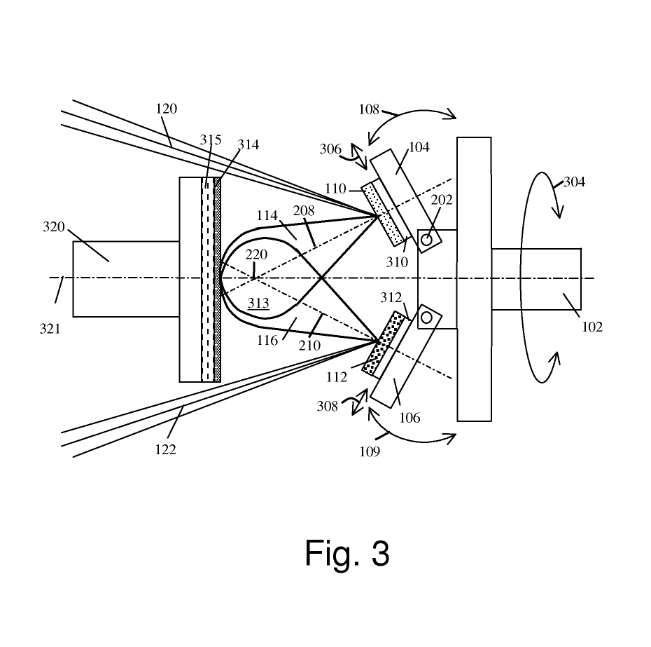

The rotation axis of hinge 202 may vary, but is preferably parallel to the plane of the surface of the substrate 118 and is also preferably perpendicular to a plane containing the two plume axes 208, 210. Alternatively the hinge axis may be perpendicular to a plane containing the plume axis 210 and a center axis of the substrate, perpendicular to the substrate. Such axis coincides with axis 208 in FIG. 2 and axis 321 in FIG. 3.

FIG. 3 depicts an exemplary schematic diagram of an alternative multiple laser system and illustrates additional optional features. For ease of discussion, only two laser beams 120 and 122 are shown in the figure. Additional beams and additional targets may be added. Referring to FIG. 3, beams 120 and 122 strike targets 110 and 112 respectively. Targets 110 and 112 are mounted on target holders 310 and 312 respectively. The target holders are mounted on bases 104 and 106 respectively. The bases are mounted on a cooling stage 102. The substrate stage 320 laced in front of the targets. The laser beams strike the targets and create plumes of their materials 114 and 116 respectively that overlap in region 313 (also referred to as a mixing volume 313) over deposited film 314 on substrates 315. FIG. 3 shows an alternative tilt angle wherein the plume axes intersect in front of the substrate at location 220. Location 220 is typically close to the substrate and past half way from the target 110 to the substrate 315. The cooling stage can rotate around its axis 321 along direction 304 to facilitate switching the targets and/or rastering. Target holders 310 and 312 can move in lateral directions 306 and 308 with respect to the corresponding laser beams to facilitate rastering and uniform exposure of the targets to the laser beams. Bases 104 and 106 tilt along directions 108 and 109 respectively to adjust overlapping region 313 between the plumes. In one variation, the bases 104 and/or 106 may be adjusted by external controls while under vacuum in the chamber.

### Pulsed Laser Ablation/Deposition System

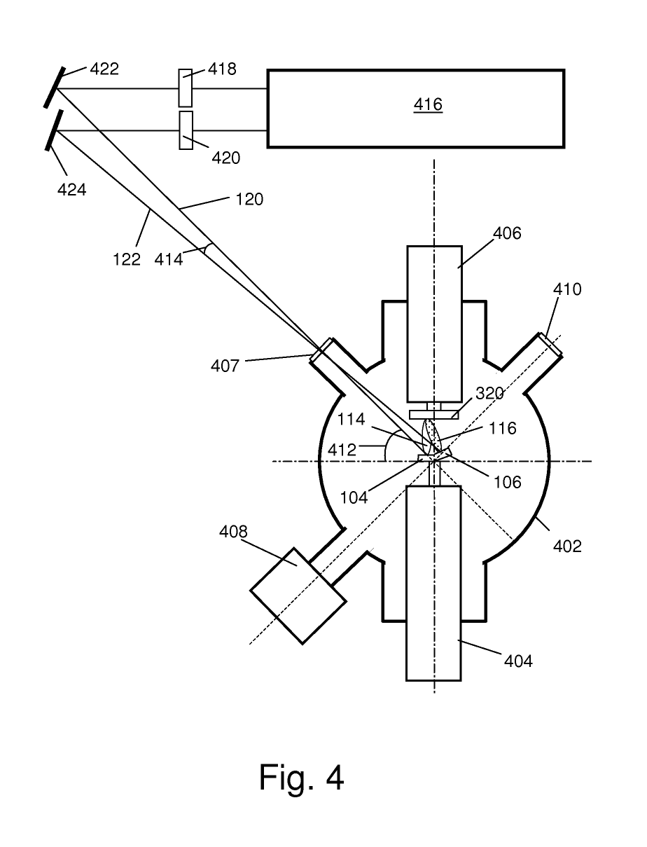

FIG. 4 shows a top view of an exemplary PLD setup of a dual laser beam deposition system that includes a pulsed laser and vacuum chamber. Referring to FIG. 4, the spherical vacuum chamber 402 provides access and mounting ports for various components of the system. Target manipulator 404 holds target carousel 104 (and the holder of the first target 110—not shown) and the second tilted holder 106 of the second target 112 (not shown). Substrate manipulator 406 holds target stage 320. Flange 407 with optical window is the optical port for laser beams 120 (1064-nm wavelength) and 122 (532-nm wavelength). RHEED device 408 is attached to the vacuum chamber to monitor the thickness of the deposited film. Flange 410 with optical window is for observation and mounting a video camera. 412 is the angle (45°) between the first laser beam 120 and the horizontal axes of the chamber. 414 is the angle between the two laser beams. Laser 416 (Nd:YAG Q-switched laser with the second harmonic generation unit) generates the two pulsed laser beams. Computer controlled optical shutters 418 and 420 independently block the laser beams in a controllable way in order to regulate the mixing proportion of the materials of both targets in the deposited film. Tilting minors 422 and 424 control the positions of the laser beams on the corresponding targets. They may be motorized to provide rastering of the laser beams along the targets.

### Plume Characteristics

The plume size varies from 2.5 cm to 4 cm. Once the plasma is formed, the plume propagated from the target towards the substrate. Overlapping region of the two plumes is the location of the chemical or physical (in our case) interaction between the ions of the component materials resulting in a homogenous mixed plume forming the thin film.

The typical velocity of the plume front is ˜5×10³ m/s. The front of the plume typically reaches a substrate at a distance of 5 cm from the target in 10 μs after the laser pulse. The density of the plume (number of ions per unit of volume) is the highest near the target and decays gradually towards the substrate at any given time after the laser pulse. The maximum density near the target is of the order of 3×10¹⁷ ions/cm³. When the plume expends in the ambient gas at a typical pressure of up to 200 mTorr, its front creates a shock wave in the gas. The plume distribution becomes less gradual and more square-type with abrupt drop of the ion density near the region where the shock wave is formed. In this region the pre-mature condensation of the target material can occur. At higher pressure of the ambient gas, the pre-mature condensation can happen before the plume reaches the substrate. Experimental observation of the plume dynamics can be performed with the ion (Langmuir) probe or with a high-speed video camera detecting the glow of the plume. The plume always expends in the direction normal to the surface of the target. The angle of the incidence of the laser beam can vary, depending on the actual configuration of the deposition chamber. Typically, at higher incidence angle more of the laser energy is reflected without being dissipated in the target. Accordingly, the less incidence angle (the laser beam direction close to the normal to the surface of the target) is preferred for delivering more laser beam energy to the target.

The gas pressure and/or the gas type may accelerate or enhance the formation of the thin film. The angle of incidence of each plume is adjusted to produce the maximum overlap of the two plumes.

### Rastering

Rastering of the laser beam over the target is used to avoid forming a crater in one spot of the target and cracking it before the film is completed. Rastering can be achieved by moving the target and keeping the laser beam fixed, as previously described in FIG. 3. Alternatively, rastering can be achieved by a slight vibration of one of the mirrors in the laser beam delivering optical channel to force the beam to travel over the target and ablate it evenly (see FIG. 4). Variation of beam position can periodically change the overlapping conditions of the plumes, but also can make the resulting film formed on the surface more even. The size of the laser spot may be any desired size, however, typically does not exceed 1 cm². The laser pulse may be any energy level necessary for a particular target, however, an exemplary laser beam may typically deliver about 1 J of energy in such a spot (the exemplary energy density may be about ˜1 J/cm²).

Typically, the laser pulse repetition rate varies from 1 to 10 Hz. Typical laser pulse duration is ˜10 ns. The laser power density is accordingly ˜0.1 GW/cm² or higher (for more focused laser beam).

### Deposition Monitor, RHEED

The popular method of real-time monitoring of the growth of inorganic monocrystalline films during the PLD process is based on the reflected high energy electron diffraction (RHEED). RHEED instrument is installed in the exemplary vacuum PLD chamber. Periodic oscillations of the brightness of individual diffraction spots in the electron diffraction pattern in the fluorescent screen give exact account of the number of the atomic layers being formed in a highly ordered ultrapure thin monocrystalline film. Each peak in the oscillating spot brightness represents the forming of a new monolayer. Since the degree of order is at a maximum once a new monolayer has been formed, the spots in the diffraction pattern have maximum intensity since the maximum number of diffraction centers of the new layer contribute to the diffracted beam. The overall intensity of the oscillations is dropping the more layers are grown. This is because the electron beam was focused on the original surface and gets out of focus the more layers are grown. Each full period corresponds to formation of a single atomic layer. The oscillation period is highly dependent on the material system, electron energy and incident angle, so researchers obtain empirical data to correlate the intensity oscillations and film coverage before using RHEED for monitoring film growth. Since the polymer nano-composite films are not perfectly ordered or rather perfectly disordered (amorphous), more suitable can be, for instance, a standard oscillating quartz plate monitor placed next to the substrate. Post-depositions methods might include atomic force microscope (which was used in our experiment), stylus profilometer, optical interferometric microscope (for the films with a thickness of fractions of a micron), and optical reflectometer. The laser deposition process can be calibrated by relating the thickness of the film measured after the deposition to the number of the laser pulses used. In such a way the thickness of the film can be controlled by selecting a certain number of the laser pulses used.

### C. Method

Referring to FIG. 3, an exemplary process will now be described comprising the following steps:
1) Targets are prepared, pre-cooled and preserved in solid state.
2) Targets 110 and 112 and substrate 315 are mounted on their holders.
3) Vacuum is created in the vacuum chamber and a carrier gas is fed in.
4) The targets are exposed to the corresponding laser beams.
5) Bases 104 and 106 are tilted in order to obtain a desirable overlapping region 313 between plumes 114 and 116.
6) The PLD process is conducted until film 314 of a desirable thickness is obtained on substrates 315.
7) The laser beam illumination and target selection can be varied to vary the mixture of the composite film 314 across the thickness of the film.
8) The laser beams can be attenuated to achieve different proportions of the components in the composite film.
9) Bases 104 and 106 can be tilted along directions 108 and 109 respectively in order to achieve the optimal overlapping region 313 of plumes 114 and 116 over substrate 315.
10) Stage 102 can be rotated along direction 304 around its axis to switch the targets between the beams.
11) Target holders 310 and 312 can move along directions 306 and 308 lateral to the respective beams in order to achieve rastering and uniform consumption of the target materials.

### D. Alternate Embodiments

In one alternative embodiment, target 110 can be made of solid polymer, such as poly(methyl methacrylate) known as PMMA and target 112 made of metal, such as gold. Laser beams 120 and 122 can be of the same wavelength, such as 1064 nm (the fundamental harmonic of an Nd:YAG laser) or can have different wavelengths: 255 nm (the 4-th, UV harmonic of the Nd:YAG laser) for the polymer target 110 and 532 (the 2-nd, visible harmonic of the Nd:YAG laser) for metal target 112.

In yet another alternative embodiment, the target 110 is made of polymer PMMA dissolved in as solvent, such as toluene or chlorobenzene, and frozen to a solid state in liquid nitrogen. Then the target is mounted on cooling stage 102 continuously cooled with circulating liquid nitrogen. Then the target is exposed to the UV laser beam to implement the matrix assisted pulsed laser evaporation (MAPLE) process in which the frozen solvent dissipates the energy of the UV laser into heat transferred to the polymer that evaporates without dissociation and condensates on substrate 315 together with the material from the second target 112 to form a polymer nano-composite film 314.

In yet another alternative embodiment, the number of targets and laser beams of different wavelengths are more than two to implement PLD of multi-composite films.

In yet another alternative embodiment, the first laser wavelength is chosen to be in the mid-IR, namely in resonance with the frequency of the vibrational modes of the polymer molecules of the polymer target 110 to implement the resonance IR (RIR) PLD of polymer nano-composites, which does not cause dissociation of the deposited polymer material.

In yet another alternative embodiment the first laser wavelength is chosen to be in the mid-IR, namely in resonance with the frequency of the vibrational modes of the molecules of the frozen solvent matrix of the frozen polymer-solvent target 112 to implement the resonance RIR MAPLE of polymer nano-composites, which the most gentle laser deposition process suitable for highly sensitive polymer molecules, such as proteins or DNAs.

### Dual Pulsed Laser Deposition (DPLD)

The dual pulsed laser deposition in accordance with the present disclosure enables precise control of films that would be very difficult or impractical to grow using single target techniques. The dual target, dual laser approach allows the separation of the components of a combination film and optimization of the evaporation conditions for each component. For example, each component may utilize exactly the best laser wavelength and energy for best energy absorption (resulting in efficient ablation) and minimum damage to the material, without having to be limited by the presence of the other component. Each component may separately select DPLD, MAPLE DPLD, or other techniques for optimum ablation of each component. Also, the rate of deposition for each component may be separately controlled. This is especially applicable where one component may be an organic polymer and the other component may be an inorganic nanocrystal. The organic polymer may be advantageously deposited using MAPLE techniques; whereas, the nanocrystal may be deposited by direct laser ablation techniques.

One exemplary process and material will now be described in detail. A useful class of composite films comprises films containing nanocrystals doped with ions of rare earth (RE) elements. These RE doped nanocrystals have unique physical, chemical and optical properties particularly attributed to nanometer size of the particles. The films have great potential of being used in applications spanning from new types of lasers, especially blue and UV lasers, phosphorous display monitors, optical communications, and fluorescence imaging.

### Upconversion Compounds Used for the Composite Film Deposition

One exemplary property of a class of these RE doped nanocrystals is the upconversion of optical energy, in particular, laser energy. In general, efficient hosts for energy upconversion may be based on materials with low phonon energies which minimize the non-radiative multi-phonon relaxation process of the RE dopant. A desirable exemplary group of efficient upconversion phosphors is based on fluorides which are doped with Yb³⁺ and Er³⁺ or Yb³⁺ and Ho³⁺ or Yb³⁺ and Tm³⁺. Hexagonal-phase NaYF₄ (β-NaYF₄) crystals is a particularly efficient host material for upconverting RE ions due to the low phonon energy of the crystal lattice.

RE doped materials of different compositions, shapes and size distributions may be prepared by various synthetic methods such as chemical vapor deposition, sol-gel process, micro-emulsion techniques, gas phase condensation methods, hydrothermal methods and laser ablation. One exemplary preparation will be described in detail. NaYF₄ crystals co-doped with trivalent RE ions may be synthesized using a solution based technique (wet process) in the presence of Na₂-ethylenediaminetetraacetic acid (EDTA). After annealing at a temperature of 400° C. or 600° C. very strong upconversion fluorescence may be observed by the naked eye. Three efficient rare-earth compounds have been developed and incorporated in polymer nanocomposite light-emitting films using DPLD:

(a) NaYF₄:Er³⁺, Yb³⁺,

(b) NaYF₄:Ho³⁺, Yb³⁺, and

(c) NaYF₄:Tm³⁺, Yb³⁺.

The micro-powders with an average grain size of ˜1 ˜m were prepared by the wet method (described below) and compressed in solid pellets with a hydraulic press. The molar fractions of the rear earth (RE) components in all three compounds are nominally NaYF₄:X³⁺ (1.6%), Yb³⁺ (9.6%), where the host NaYF₄=molar 100% and X stands for Er, Ho, or Tm. The X³⁺ may be molar 1.5% of the host plus or minus 0.75%, i.e., 0.75% to 2.25%, preferably plus or minus 0.5%, i.e., 1.0% to 2.0%. The Yb³⁺ may be molar 9.6% of the host plus or minus 4.8%, i.e., 4.8% to 1.44%, preferably plus or minus 3.2%, i.e., 6.4% to 12.8%. It is expected that the proportions prepared in the target are transferred to the film during deposition.

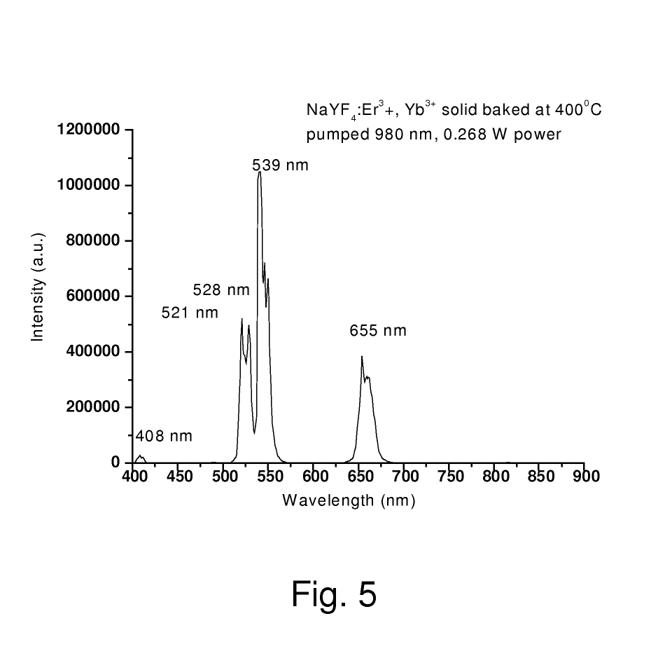

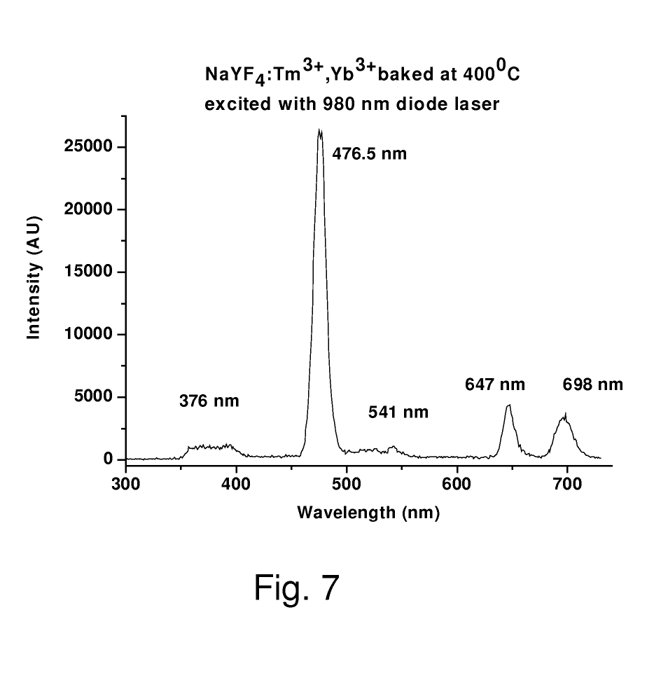

The NaYF₄:Yb³⁺, Er³⁺ crystals (compound (a)) were prepared in the presence of Na₂-ethylenediaminetetraacetic acid (EDTA) using the co-precipitation procedure to obtain homogeneous nucleation. First 0.5 mol of NaF was dissolved in about 60 ml of water. An aqueous rare-earth chloride solution was prepared by mixing 16 ml of 0.2-mol YCl₃, 3.4 ml of 0.2-mol YbCl₃ and 0.6 ml of 0.2-mol ErCl₃. The YCl₃ solution was obtained by dissolving Y₂O₃ in hydrochloric acid and adjusting to pH 2 to avoid any hydrolysis. The rare-earth chloride solution was allowed to mix with 20 ml of 0.2-mol EDTA solution for metal-EDTA complex to occur. All the rare-earth chlorides, EDTA and NaF were obtained from Aldrich and the Y₂O₃ was synthesized in the lab using Y(NO₃)₃ and Na₂CO₃ from Aldrich. The EDTA complex solution was quickly introduced into the NaF solution and the mixture was allowed to stir vigorously for several hours. After stirring, the solution was allowed to sit overnight for the precipitate to settle. The precipitate was filtered, washed several times with distilled water and with ethanol. The precipitate was dried under vacuum to remove any traces of water. The NaYF₄:Yb³⁺, Er³⁺ crystals prepared in the above procedure did not show initially any upconversion fluorescence. However, after the dried precipitate was annealed to a temperature of 400° C. for a period of one hour, bright green upconversion was observed under 980 nm laser diode excitation. As a result, a hexagonal NaYF₄:Yb³⁺, Er³⁺ phase was obtained in addition to the cubic phase. Compounds (b) and (c) were synthesized in a similar way using HoCl₃ and TmCl₃ respectively instead of ErCl₃. Compounds (a) and (b) exhibited brilliant upconverted green emission (with a quantum yield of ˜1%) primarily at ˜540 nm and compound (c)—red emission (at ˜647 nm) and blue emission (470 nm) being pumped with an infra-red pump at 980 nm. (Note: about or approximately equal to x nanometers when referring to emission peak wavelengths means within three percent.) The quantum yield (upconversion power ratio) appears to be typically from 0.1% to 1.5%) Optical fluorescent spectroscopy of the upconversion powders was conducted using a 980-nm laser diode PL980P330J from Thorlabs (330-mW maximum power, quantum-well laser chip, pigtailed with a wavelength stabilizing fiber Bragg grating) as a pumping source. In all the measurements, the samples were at room temperature. Optical fluorescent spectra were taken with the Princeton Instruments 500-mm-focal-length Spectra Pro (SP—2500i) imaging spectrometer/monochromator equipped with 1200 gr/mm (blazed at 500 nm) holographic diffraction grating and PI-Max 1024 HQ Digital Intensified CCD Camera system. Before the spectroscopic measurements, the crystalline powders were compressed into flat pellets. The emission measurements were made in reflectance mode using a sample chamber with the sample pellets placed approximately at an angle of 45° with respect to the optical axis of the entrance slit of the monochromator. Fluorescence spectra of the compounds are presented in FIGS. 5 through 7.

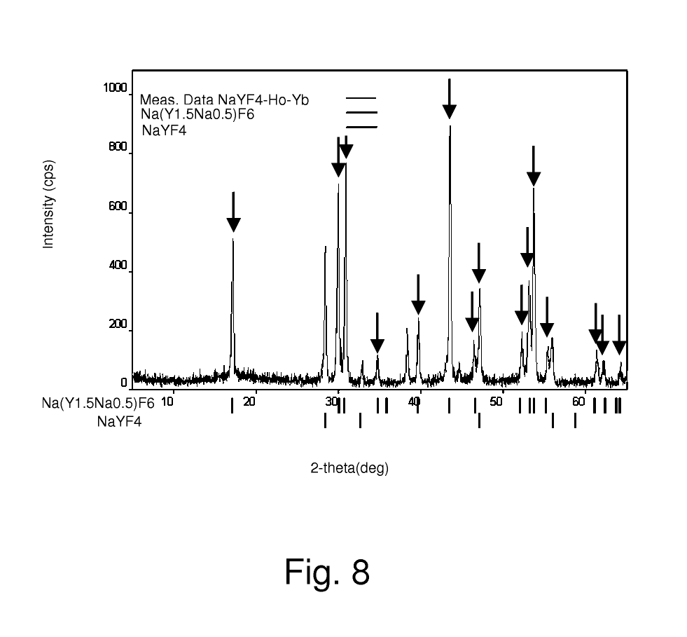

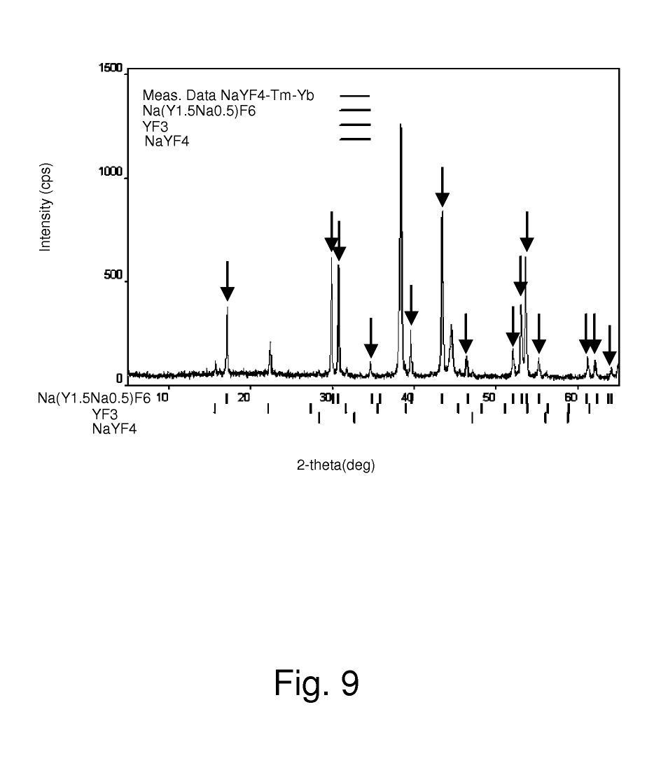

The X-ray diffraction (XRD) data for powders (b) and (c) taken with Bruker D2 Phaser X-ray diffractometer are presented in FIGS. 8 and 9. The data in FIG. 8 suggests that material (b) contains only two phases, hexagonal Na_{1.5}Y_{1.5}F₆ and cubic NaYF₄. The disordered Na_{1.5}Y_{1.5}F₆ is the majority product, but there is a much more equal ratio of the products in this sample compared to the Tm, Yb-doped sample (c) (FIG. 9). Here it appears to be about 60/40 in favor of the disordered fluoride. The two unassigned peaks at 2-thetas of 39 and 45 degrees are from the aluminum sample holder due to the small amount of the sample. Both products are highly crystalline and appear to have particle sizes above 100 nm.

From observation of FIG. 9, material (c) contains three products: Na_{1.5}Y_{1.5}F₆, NaYF₄ and YF₃. The main product is Na_{1.5}Y_{1.5}F₆. This is actually thought of as the low temperature form of NaYF₄, but is not written in that formulation since, crystallographically, the Y site is disordered as Na(Y_{1.5}Na_{0.5})F₆. This results in hexagonal symmetry P6₃/m. This material is typically prepared by low temperature techniques and will convert into cubic NaYF₄ at 691° C. This cubic NaYF₄ is also present in this sample, but only as a very minor product. The third product is YF₃. All of the products are highly crystalline and have particle sizes greater than 100 nm.

### Deposition Procedure

A sample of the solution of polymethyl(methacrylate) known as PMMA in chlorobenzene at a proportion of 1 g solids per 10 mL liquids was poured in a copper cup and frozen in liquid nitrogen. Then the copper cup with the frozen polymer solution was mounted on a double target holder (as Target 1) cooled with continuous flow of liquid nitrogen. Target 2 was made of a solid pellet prepared by compressing the powder of an upconversion powder material and retained in a holder. The laser source was a Spectra Physics Quanta Ray Nd:YAG Q-switched Lab-170-10 laser with a pulse repetition rate of 10 Hz, 850-mJ energy per pulse at the 1064-nm fundamental wavelength and 450-mJ energy per pulse at the 532-nm second harmonic. The frozen polymer Target 1 was ablated with the 1064-nm laser beam. Target 2 was ablated with the 532-nm frequency doubled Nd:YAG beam.

### Pulse Timing

In one variation, the two pulses may be simultaneous, i.e., sufficiently simultaneous in time such that the two plumes interact during deposition on the substrate. This may produce the most uniform mixture as a function of depth in the film. In another variation, the pulses may be separate or interleaved. Thus each pulse deposits a layer on top of the other. This may produce a slight layering effect; however, since the layers are very thin and may be on the order of molecular thickness, the layering may be insignificant. In a further variation, there may be an unequal number of pulses from each laser as a method of controlling proportion of components. For example, there may be one pulse from a first laser followed by 20 pulses from a second laser.

If each laser pulse deposits an equal amount, the film component ratio would be 1/20. Alternatively the two lasers may fire simultaneously for one pulse interval followed by 19 pulses from the second laser to produce the same 1/20 component ratio. For some films, the resulting layering may be tolerated. For other films requiring less layering, every pulse interval may comprise two simultaneous pulses to minimize or eliminate layering. Other techniques may be used to vary the component ratio, including but not limited to varying target composition, laser pulse energy, fluence (energy per area), or other parameter.

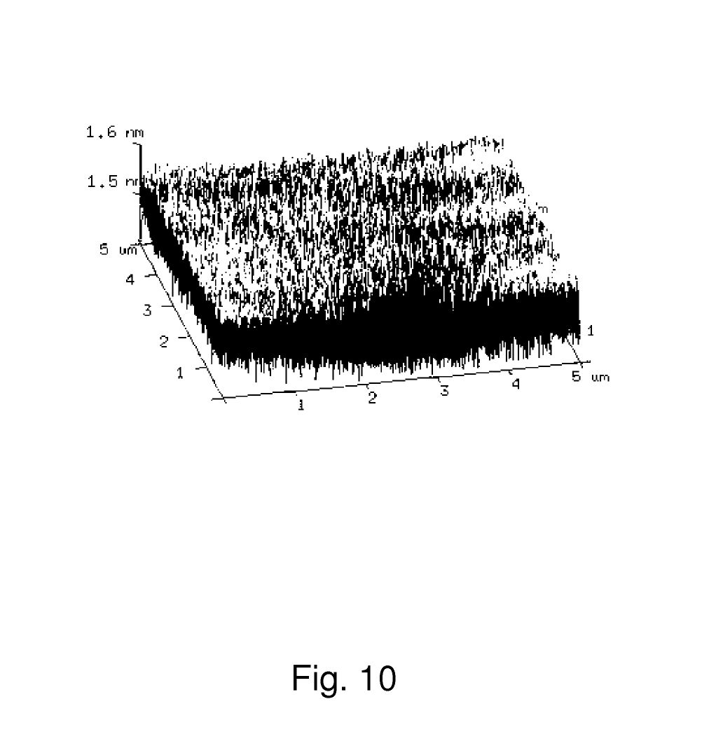

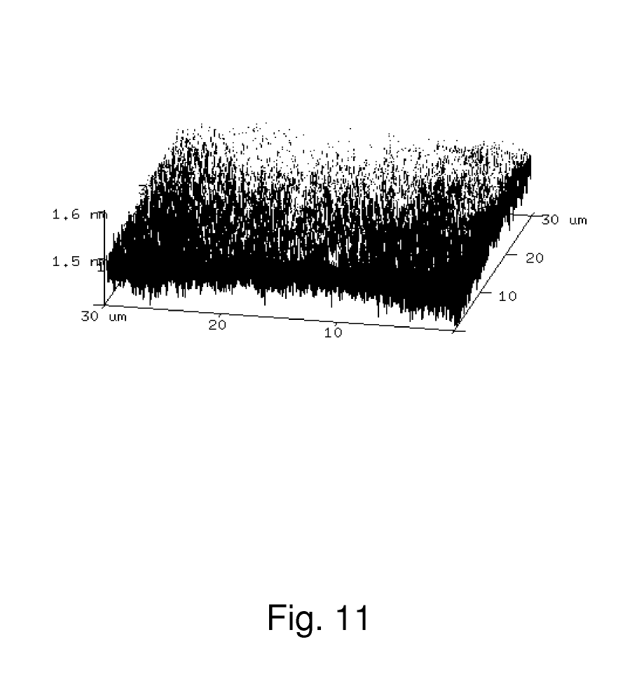

The exemplary materials of FIG. 10 and FIG. 11 were produced using a first pulse interval comprising simultaneous pulses from two lasers, a 10 ns pulsed green laser and a 10 ns pulsed infra-red laser, followed by 19 pulses from the infra-red laser alone.

During the first pulse interval, the 10-ns-long green pulse is shot, simultaneously with the ˜10-ns-long infra-red pulse. As a result, the polymer host and the inorganic dopant were deposited simultaneously (i.e., concurrently) in the layer associated with the two pulses and mixed in the film. Then the green pulse was blocked by a shutter and 19 subsequent infra-red pulses impinge on the frozen polymer target. Only the polymer material was deposited as a result of the 19 pulses. Then again the green and the 21^{st} infrared pulse were shot simultaneously, as the sequence is repeated. The sequence may be repeated as many times as desired.

The true mixing of both materials occurs only when the green and infra-red pulses impinge the targets simultaneously. The result was still a slightly stratified film (one true composite layer per 19 purely polymer layers). Regarding the proportion, the proportion may be characterized as “19 layers of pure polymer per one layer of polymer mixed with the inorganic material”. Alternatively, a uniform composite film may be produced by keeping the green and infra-red pulses with the same pulse repetition frequency and fully overlapping in time and to control the proportion by varying the fluence (pulse energy per unit of the target area) of the pulses. The fluence of the laser pulses can be controlled either using in-line laser beam attenuators (such as a pair of high-power rotating Glan-Thompson polarizers) or tighter focusing/defocusing the beams. After reaching the threshold fluence of ˜1 J/cm² (for the most of the target materials), further increase of the fluence usually leads to the proportional increase of the rate of the deposition of the target material on the substrate. For instance, if the fluence of the infra-red beam would be 20 J/cm² (tightly focused beam), and the fluence of the infra-red beam would be 1 J/cm², the truly uniform composite film with 1 portion of the inorganic material per 20 portions of the polymer (or about 5% proportion). In order to convert this proportion in more meaningful mass (weight) or molar proportion, the calibration experiments must be performed relating the laser pulse fluence to the amount of each material being deposited on the substrate.

The proportions of PMMA and inorganic may be varied over a wide range as needed for the application. Less inorganic will produce less intense visible light when illuminated by the same IR excitation. Greater inorganic will increase the visible response to the IR excitation up to the region where the film becomes opaque due to the inorganic content. At some point, the film adhesion and durability may be affected by an overload of inorganic content.

Significant advantages arise from the dual beam configuration even though the pulses may not be sufficiently simultaneous for the respective plumes to interact for each pulse deposition. First, the pulse rate is not limited by having to exchange targets mechanically to utilize a single beam. Second, targets may be more constrained in position permitting larger and more complex target holders with features such as cooling and temperature regulation.

Surface Morphology of the Composite Films Produced with DPLD

The surface roughness and the homogeneity of the deposited polymer nanocomposite films was evaluated using a Bruker Atomic Force Microscope as shown in FIGS. 10 and 11. The AFM scans indicate that the DPLD thin films came out smooth without major defects. This might be a benefit attributed to the optimal interaction between the two plumes. Substrate heating resulted in more uniform film. The roughness of the surface was measured to be near 1-2 nm rms, less than 5 nm rms for the films of 190-270 nm thickness. Although an accurate count of pulses was not recorded, it is estimated that approximately 400 infra-red pulses were used to produce the films of FIGS. 10 and 11.

Thus the DPLD process is capable of producing thin films from a few nanometers to 200 nanometers or 1000 nanometers and more, while maintaining high surface uniformity and precise mixture control on a layer by layer (pulse by pulse) basis.

### XRD Analysis

The DPLD produced polymer composite films were analyzed using X-ray diffraction (XRD) method. For comparison, the positions of the X-ray diffraction peaks of the composite film of PMMA: NaYF₄:Ho³⁺, Yb³⁺ are marked in the XRD spectrum of the initial powder material (FIG. 8) with black downward arrows. The composite film contains mainly the hexagonal product Na_{1.5}Y_{1.5}F₆ and has much less (no noticeable traces) of cubic NaYF₄ as compared to the initial upconversion powder material. The particles of the disordered Na_{1.5}Y_{1.5}F₆ product embedded in the polymer matrix are highly crystalline.

The positions of the X-ray diffraction peaks of the composite film of PMMA: NaYF₄:Tm³⁺, Yb³⁺ are also marked in the XRD spectrum of the initial powder material (FIG. 9) with black downward arrows. The polymer composite film again contains mainly the hexagonal product Na_{1.5}Y_{1.5}F₆ and has much less (no noticeable traces) of cubic NaYF₄ as compared to the initial upconversion powder material. The particles of the disordered hexagonal phase Na_{1.5}Y_{1.5}F₆ embedded in the polymer matrix are highly crystalline. The XRD data thus clearly indicate that the major hexagonal phase Na_{1.5}Y_{1.5}F₆ hosting the RE ions in the initially prepared upconversion phosphors was successfully transferred in the polymer composite films during the DPLD process.

### Fluorescence

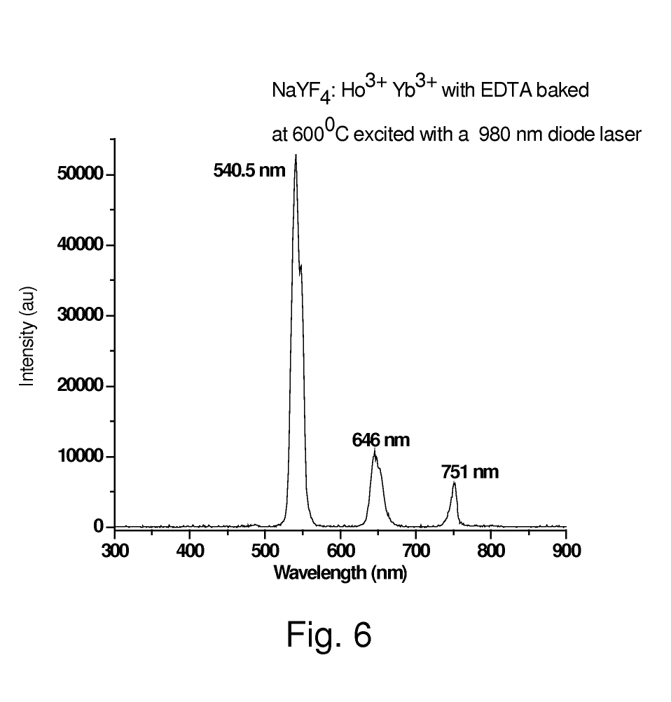

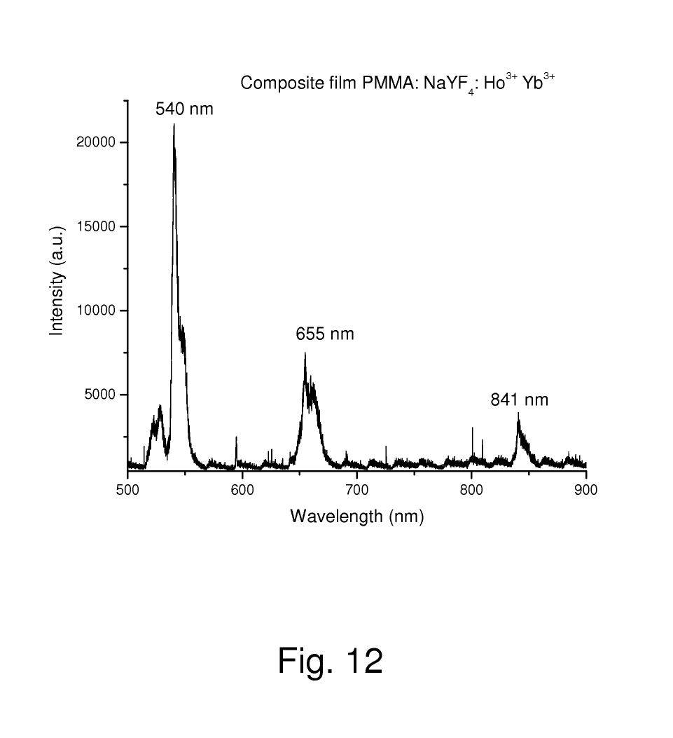

The prepared composite films were illuminated with a 200-mW laser diode (from Sky Laser) at 980-nm. Upconversion fluorescence in green or blue region was observed by the naked eye at room light. The observation results are summarized in Table 1. The exemplary fluorescence spectrum of the composite film of PMMA: NaYF₄:Ho³⁺, Yb³⁺ pumped with a 980-nm laser source is presented in FIG. 12. The spectrum was taken using similar procedure as for the upconversion powder samples. Comparison against the upconversion fluorescence spectrum of the powder of NaYF₄:Ho³⁺, Yb³⁺ (FIG. 6) indicates that the spectrum of the composite film retains the same structure of the peaks. However, the peak at 751 nm significantly weakens and the peak at 841 nm becomes more prominent in the composite film sample. The green emission peak at 540 nm in both, powder and composite film samples, remains dominant. The intensity of the 540-nm green emission from the composite film was measured to be approximately 0.1% of the pump power (980-nm) reflected from the film (oriented at 45° to the incident beam) in the monochromator. The results presented in Table 1 and FIG. 12 together with the XRD data indicate that the proposed DPLD method made possible to transfer the RE compounds in the polymer composite films preserving their structure and the upconversion fluorescence properties fully (row 1 in Table 1) or partially (rows 2 and 3 in Table 1).

TABLE 1
Comparison of the observed emission from the composite films
prepared by the DPLD method against the emission produced
by the initial RE powders

| | | Observed | | |
|---|---|---|---|---|
| | | emission | Initial | Observed |
| | | from | RE-doped | emission from |
| N | Composite film | the film | compound | the powders |
| 1 | PMMA:NaYF₄: | Bright green | NaYF₄:Er³⁺, | Bright green |
| | Er³⁺, Yb³⁺ | | Yb³⁺ | |
| 2 | PMMA:NaYF₄: | Weak green | NaYF₄:Ho³⁺, | Bright green |
| | Ho³⁺, Yb³⁺ | | Yb³⁺ | |
| 3 | PMMA:NaYF₄: | Weak blue | NaYF₄:Tm³⁺, | Blue |
| | Tm³⁺, Yb³⁺ | | Yb³⁺ | |

### CONCLUSION

One should understand that numerous variations may be made by one skilled in the art based on the teachings herein. The present invention has been described above with the aid of functional building blocks illustrating the performance of specified functions and relationships thereof. The boundaries of these functional building blocks have been arbitrarily defined herein for the convenience of the description. Alternate boundaries can be defined so long as the specified functions and relationships thereof are appropriately performed. Any such alternate boundaries are thus within the scope and spirit of the claimed invention.

While various embodiments of the present invention have been described above, it should be understood that they have been presented by way of example only, and not limitation. Thus, the breadth and scope of the present invention should not be limited by any of the above-described exemplary embodiments, but should be defined only in accordance with the following claims and their equivalents.

What is claimed is:

1. A pulsed laser deposition system comprising:
a plurality of pulsed laser sources directed at a plurality of respective targets, said plurality of respective targets housed in a vacuum chamber; each said pulsed laser source configured to produce a respective plume of respective material from said respective target, each said respective plume having a plume axis; each said respective plume directed to a substrate surface for deposition of said respective material on said substrate surface.

2. The pulsed laser deposition system of claim 1, wherein said plurality of respective plumes comprises a first plume having a first plume axis and a second plume having a second plume axis, and said first plume axis, and said second plume axis are directed to intersect at said substrate surface.

3. The pulsed laser deposition system of claim 1, wherein said plurality of respective plumes comprises a first plume having a first plume axis and a second plume having a second plume axis, and said first plume axis and said second plume axis are directed to intersect in front of said substrate surface.

4. The pulsed laser deposition system of claim 3, wherein said first plume and said second plume axis are directed to intersect near the substrate surface, closer than half way between the substrate surface and the target.

5. The pulsed laser deposition system of claim 1, wherein said plurality of targets produce a first plume and a second plume and said first plume and said second plume are directed to an overlapping region in front of said substrate surface, said overlapping region containing a portion of said first plume and a portion of said second plume.

6. The pulsed laser deposition system of claim 5, wherein at least one target of said plurality of respective targets has a mounting having an adjustable angle of the respective plume axis for improving uniformity of the deposition.

7. The pulsed laser deposition system of claim 6, wherein the target holder mounting comprises a hinge between the target holder and the base, wherein the hinge has a rotational axis parallel to a plane of said substrate and perpendicular to a plane containing the first plume axis and the second plume axis.

8. The pulsed laser deposition system of claim 1, wherein said plurality of pulsed laser sources comprises a first laser source for producing a first plume and a second laser source for producing a second plume and said first laser source and said second laser source are configured to produce pulses sufficiently simultaneous in time to produce concurrent deposition from said first plume and said second plume.

9. The pulsed laser deposition system of claim 1, wherein said plurality of pulsed laser sources comprises a first laser source for depositing a first deposited material and a second laser source for depositing a second deposited material and a ratio of said first deposited material to said second deposited material is adjustable by adjusting a laser fluence of said first laser source.

10. The pulsed laser deposition system of claim 1, wherein a first laser source and a second laser source of said plurality of laser sources have differing wavelengths.

11. A method for depositing a composite film on a substrate comprising:
directing a plurality of pulsed laser sources to impinge a respective plurality of targets and produce a respective plurality of plumes, each target of said respective plurality of targets containing a respective material for deposition on said substrate;
orienting said respective plurality of targets to direct each plume of said respective plurality of plumes to a plume mixing volume in front of said substrate;
triggering said plurality of laser sources to produce respective plumes concurrently in time to mix said plumes in said plume mixing volume in front of said substrate and concurrently deposit said respective materials to produce said composite layer on said substrate.

12. The method as recited in claim 11, wherein at least two targets of said plurality of targets have a surface plane and a plume axis normal to said surface plane passing through the surface plane at a center of laser focus on said surface plane; and said plume axes of said at least two targets are directed to intersect in front of said substrate.

13. The method as recited in claim 11, wherein the triggering step is repeated to deposit one or more additional composite layers.

14. The method as recited in claim 13, further including a step of adjusting a deposition rate of at least one respective material by adjusting a respective laser fluence.

15. The method as recited in claim 13, wherein
the first target is PMMA solution in Chlorobenzene frozen to the temperature of liquid nitrogen;
and the first pulsed laser is an infrared laser;
and the second target is NaYF₄:Er³⁺, Yb³⁺;
and the second pulsed laser is a green laser;
and the resulting composite film is PMMA: NaYF₄:Er³⁺ Yb³⁺ said composite film having a surface roughness of less than 5 nanometers rms.

15. The method as recited in claim 13, wherein
the first target is PMMA solution in Chlorobenzene frozen to the temperature of liquid nitrogen;
and the first pulsed laser is an infra-red laser;
and the second target is NaYF₄:Ho³⁺, Yb³⁺;
and the second pulsed laser is a green laser;
and the resulting film is PMMA: NaYF₄:Ho³⁺, Yb³⁺.

16. The method as recited in claim 13, wherein
the first target is PMMA solution in Chlorobenzene frozen to the temperature of liquid nitrogen;
and the first pulsed laser is an infrared laser;
and the second target is NaYF₄:Tm³⁺, Yb³⁺;
and the second pulsed laser is a green laser;
and the resulting film is PMMA: NaYF₄:Tm³⁺, Yb³⁺.

17. A polymer composite film deposited on a substrate comprising:
PMMA: NaYF₄: x, Yb³⁺, wherein x is a rare earth ion; said polymer composite film having upconversion fluorescence property of emission with characteristic upconversion fluorescence spectral peaks, wherein NaYF₄ comprises crystallographically a Na_{1.5}Y_{1.5} F₆ form; said x being present in a molar ratio of 1.5% plus or minus 0.75% compared to NaYF₄, and Yb³⁺ being present in a molar ratio of 9.6% plus or minus 4.8% compared to NaYF₄.

18. The polymer composite film as recited in claim 17, wherein x is Er³⁺ and the polymer composite film is capable of exhibiting said upconversion fluorescence peaks at about 540 nanometers and about 655 nanometers when excited by 980 nanometer illumination.

19. The polymer composite film as recited in claim 17, wherein x is Ho³⁺ and the polymer composite film is capable of exhibiting said upconversion fluorescence peaks at about 540 nanometers and about 655 nanometers and about 851 nanometers when excited by 980 nanometer illumination.

20. The polymer composite film as recited in claim 17, wherein x is Tm³⁺ and the polymer composite film is capable of exhibiting said upconversion fluorescence peaks at about 470 nanometers and about 647 nanometers when excited by 980 nanometer illumination.
